(19) United States
(12) Patent Application Publication
(10) Pub. No.: US 2024/0339975 A1
(43) Pub. Date: Oct. 10, 2024

(54) AMPLIFIER WITH CAPABILITY OF GAIN COMPENSATION AND PIPELINED ANALOG-TO-DIGITAL CONVERTOR INCLUDING THE SAME

(71) Applicant: Realtek Semiconductor Corporation, Hsinchu (TW)

(72) Inventors: Jian-Ru LIN, Hsinchu (TW); Kai-Yue LIN, Hsinchu (TW); Wei-Jyun WANG, Hsinchu (TW)

(21) Appl. No.: 18/602,056

(22) Filed: Mar. 12, 2024

(30) Foreign Application Priority Data
Apr. 7, 2023 (TW) 112113170

(51) Int. Cl. H03F 3/45; H03F 1/08; H03M 1/06

(52) U.S. Cl. CPC H03F 3/45076; H03F 1/08; H03M 1/0607

(57) ABSTRACT

An amplifier includes a first differential input pair, a reset circuit, a first compensation circuit and a second compensation circuit. First differential input pair includes a first non-inverting input terminal and a first inverting input terminal, and is configured to amplify a voltage difference between first non-inverting input terminal and first inverting input terminal to generate a non-inverting output voltage and an inverting output voltage of amplifier. Reset circuit is coupled with first differential input pair, and is configured to reset non-inverting output voltage and inverting output voltage of amplifier according to a reference voltage. First compensation circuit is configured to provide a first compensation voltage to first non-inverting input terminal, and first compensation voltage is positively correlated with non-inverting output voltage. Second compensation circuit is configured to provide a second compensation voltage to first inverting input terminal, and second compensation voltage is positively correlated with inverting output voltage.

### CROSS-REFERENCE TO RELATED APPLICATION

This application claims priority to Taiwan Application Serial Number 112113170, filed Apr. 7, 2023, which is herein incorporated by reference.

### BACKGROUND

### Field of Invention

The present disclosure relates to an amplifier and an analog-to-digital convertor. More particularly, the present disclosure relates to an amplifier with a capability of gain compensation and a pipelined analog-to-digital convertor including the same.

### Description of Related Art

Amplifiers are widely used in various analog circuits. For example, each stage of a pipelined analog-to-digital convertor includes an amplifier configured to amplify the residual signal. Amplifiers usually include feedback paths to form closed loops, and gains of amplifiers are determined by resistors and capacitors on closed loops. However, in order to improve an accuracy of a gain, an open-loop gain and a bandwidth of an amplifier body need to be designed high enough so that high operating voltage and high power consumption are required, which makes it unsuitable for an advanced semiconductor manufacturing processes. In contrast, an open-loop amplifier is configured to alternately switch between a reset phase and an amplification phase, and uses circuit amplification characteristics of an open loop to alleviate requirements on a bandwidth and an gain of an amplifier to save power consumption. However, a gain of an open-loop amplifier may be reduced due to a coupling effect of parasitic capacitors. For the foregoing reason, there is a need to provide a suitable amplifier and a suitable analog-to-digital convertor to solve the problems of the prior art.

### SUMMARY

One aspect of the present disclosure provides an amplifier, including a first differential input pair, a reset circuit, a first compensation circuit and a second compensation circuit. The first differential input pair includes a first non-inverting input terminal and a first inverting input terminal, and is configured to amplify a voltage difference between the first non-inverting input terminal and the first inverting input terminal in order to generate a non-inverting output voltage and an inverting output voltage of the amplifier. The reset circuit is coupled to the first differential input pair, and is configured to reset the non-inverting output voltage and the inverting output voltage according to a reference voltage. The first compensation circuit is configured to provide a first compensation voltage to the first non-inverting input terminal, and the first compensation voltage is positively correlated with the non-inverting output voltage. The second compensation circuit is configured to provide a second compensation voltage to the first inverting input terminal, and the second compensation voltage is positively correlated with the inverting output voltage.

Another aspect of the present disclosure provides an amplifier, including a first differential input pair, a reset circuit, a non-inverting output wire and an inverting output wire. The first differential input pair includes a first non-inverting input wire and a first inverting input wire, and is configured to amplify a voltage difference between the first non-inverting input wire and the first inverting input wire, in order to generate a non-inverting output voltage and an inverting output voltage. The reset circuit is coupled to the first differential input pair, and is configured to reset the non-inverting output voltage and the inverting output voltage of the amplifier according to a reference voltage. The non-inverting output wire is configured to transmit the non-inverting output voltage, and a portion of the non-inverting output wire is disposed adjacent to the first non-inverting input wire to form a first compensation capacitor with the first non-inverting input wire. The first compensation capacitor is configured to provide a first compensation voltage positively correlated with the non-inverting output voltage to the first non-inverting input wire. The inverting output wire is configured to transmit the inverting output voltage, and a portion of the inverting output wire is disposed adjacent to the first inverting input wire to form a second compensation capacitor with the first inverting input wire. The second compensation capacitor is configured to provide a second compensation voltage positively correlated with the inverting output voltage to the first inverting input wire.

Another aspect of the present disclosure provides a pipelined analog-to-digital convertor (ADC), including a convertor circuitry. The convertor circuitry includes an analog-to-digital convertor, a digital-to-analog convertor (DAC), a subtractor and an amplifier. The DAC is configured to convert an output of the ADC. The subtractor is configured to subtract the output of the DAC from an input of the ADC. The amplifier includes a first differential input pair, a reset circuit, a first compensation circuit and a second compensation circuit. The first differential input pair includes a first non-inverting input terminal and a first inverting input terminal configured to receive an output of the subtractor, and is configured to amplify a voltage difference between the first non-inverting input terminal and the first inverting input terminal in order to generate a non-inverting output voltage and an inverting output voltage. The reset circuit is coupled to the first differential input pair, and is configured to reset the non-inverting output voltage and the inverting output voltage of the amplifier according to a reference voltage. The first compensation circuit is configured to provide a first compensation voltage to the first non-inverting input terminal, and the first compensation voltage is positively correlated with the non-inverting output voltage. The second compensation circuit is configured to provide a second compensation voltage to the first inverting input terminal, and the second compensation voltage is positively correlated with the inverting output voltage.

One of advantages of the above-mentioned amplifier and pipeline analog-to-digital convertor is that a gain of an amplifier can be compensated and ensure that a gain of an amplifier will not be reduced due to a coupling effect of parasitic capacitors.

### BRIEF DESCRIPTION OF THE DRAWINGS

The present disclosure can be more fully understood by reading the following detailed description of the embodiment, with reference made to the accompanying drawings as follows:

FIG. 1 depicts a schematic diagram of an amplifier according to one embodiment of the present disclosure.

FIG. 2 depicts a schematic diagram of an amplifier according to one embodiment of the present disclosure.

FIG. 3 depicts a schematic diagram of an amplifier according to one embodiment of the present disclosure.

FIG. 4 depicts a schematic diagram of an amplifier according to one embodiment of the present disclosure.

FIG. 5 depicts a partial circuit layout schematic diagram of the amplifier of FIG. 4 according to one embodiment of the present disclosure.

FIG. 6 depicts a schematic diagram of an arrangement of wires of FIG. 4 according to one embodiment of the present disclosure.

FIG. 7 depicts a schematic diagram of an arrangement of wires of FIG. 4 according to one embodiment of the present disclosure.

FIG. 8 depicts a simplified functional block diagram of a pipelined analog-to-digital convertor according to one embodiment of the present disclosure.

FIG. 9 depicts a simplified functional block diagram of a pipelined analog-to-digital convertor according to one embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

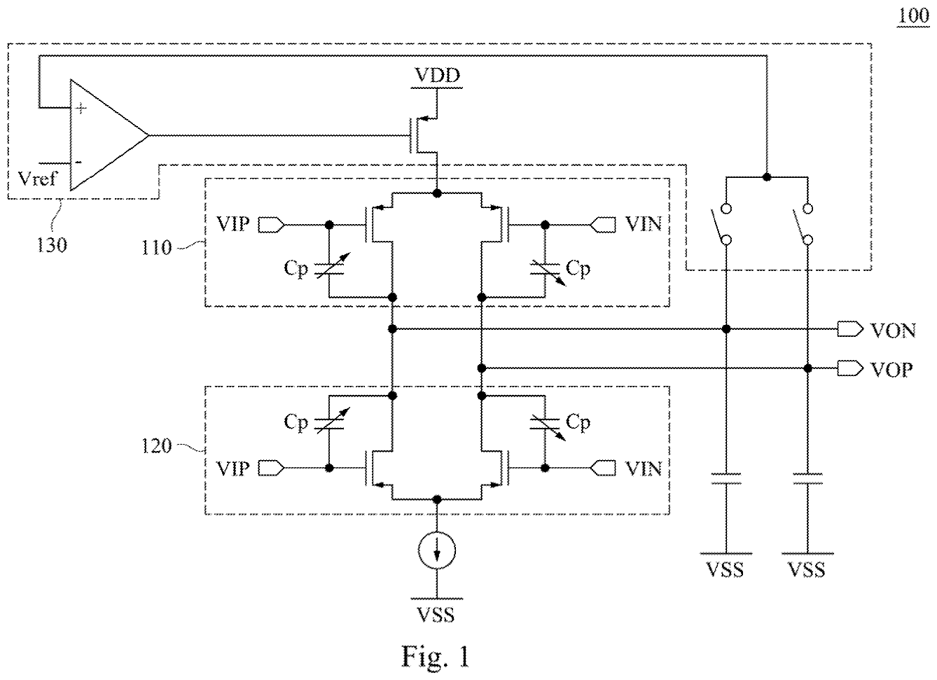

FIG. 1 depicts a schematic diagram of an amplifier 100 according to one embodiment of the present disclosure. The amplifier 100 includes a differential input pair 110, a differential input pair 120 and a reset circuit 130. The differential input pairs 110 and 120 are configured to amplify a voltage difference between a non-inverting input voltage VIP and an inverting input voltage VIN, in order to generate a non-inverting output voltage VOP and an inverting output voltage VON. The reset circuit 130 is configured to periodically reset, according to the reference voltage Vref, the non-inverting output voltage VOP and the inverting output voltage VON to be close to a reference voltage Vref.

In this embodiment, the inverting input voltage VIN is higher than the non-inverting input voltage VIP, so that the non-inverting output voltage VOP gradually decreases and the inverting output voltage VON gradually increases. In this time, changes of the non-inverting output voltage VOP and the inverting output voltage VON affect the inverting input voltage VIN and the non-inverting input voltage VIP through a coupling effect of a plurality of gate-drain parasitic capacitors Cp of the differential input pairs 110 and 120. Specifically, the parasitic capacitors Cp provide negative feedbacks, so that the higher inverting input voltage VIN is pulled down and the lower non-inverting input voltage VIP is raised, thereby reducing a gain of the amplifier 100.

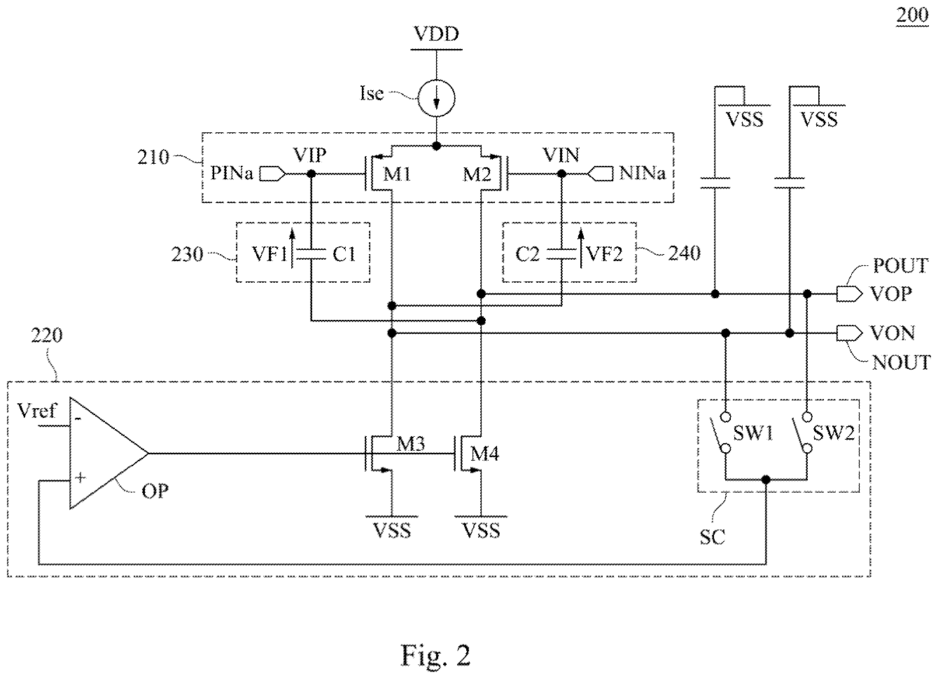

FIG. 2 depicts a schematic diagram of an amplifier 200 according to one embodiment of the present disclosure. The amplifier 200 includes a differential input pair 210, a reset circuit 220, a compensation circuit 230, a compensation circuit 240, a current source Ise, a non-inverting output terminal POUT and an inverting output terminal NOUT. The non-inverting output terminal POUT and the inverting output terminal NOUT are configured to output the non-inverting output voltage VOP and the inverting output voltage VON respectively. The current source Ise is coupled between a power supply terminal VDD and the differential input pair 210. The amplifier 200 uses compensation voltages VF1 and VF2 provided by the compensation circuits 230 and 240 to offset (or to compensate) the negative feedbacks provided by the parasitic capacitors of the differential input pair 210 (not shown in FIG. 2), in order to compensate the gain of the amplifier 200 and ensure that the gain of the amplifier 200 will not be reduced due to the coupling effect of the parasitic capacitors.

The differential input pair 210 includes a transistor M1, a transistor M2, a non-inverting input terminal PINa and an inverting input terminal NINa. The non-inverting input terminal PINa and the inverting input terminal NINa are respectively configured to receive the non-inverting input voltage VIP and the inverting input voltage VIN. The differential input pair 210 is configured to amplify a voltage difference between the non-inverting input voltage VIP and the inverting input voltage VIN (i.e., a voltage difference between the non-inverting input terminal PINa and the inverting input terminal NINa), in order to provide the non-inverting output voltage VOP and the inverting output voltage VON to the non-inverting output terminal POUT and the inverting output terminal NOUT respectively. The transistor M1 is coupled between the current source Ise and the inverting output terminal NOUT, and a gate of the transistor M1 is configured to receive the non-inverting input voltage VIP from the non-inverting input terminal PINa. The transistor M2 is coupled between the current source Ise and the non-inverting output terminal POUT, and a gate of the transistor M2 is configured to receive the inverting input voltage VIN from the inverting input terminal NINa. In addition, the transistors M1 and M2 are coupled to the power supply terminal VDD through the current source Ise.

The reset circuit 220 is configured to periodically use the reference voltage Vref to adjust the non-inverting output terminal POUT and the inverting output terminal NOUT, in order to periodically reset the non-inverting output voltage VOP and the inverting output voltage VON to be close to the reference voltage Vref. The reset circuit 220 includes an operational amplifier OP, a transistor M3, a transistor M4 and a switch circuit SC. The switch circuit SC includes a switch SW1 and a switch SW2. The transistor M3 is coupled between the inverting output terminal NOUT and a power supply terminal VSS. The transistor M4 is coupled between the non-inverting output terminal POUT and the power supply terminal VSS. Gates of the transistors M3 and M4 are coupled to an output terminal of the operational amplifier OP. In some embodiments, a voltage of the power supply terminal VDD is higher than a voltage of the power supply terminal VSS.

A first input terminal of the operational amplifier OP (e.g., an inverting input terminal) is configured to receive the reference voltage Vref. By virtue of a virtual short-circuit characteristic of the operational amplifier OP, the operational amplifier OP is configured to receive a common mode voltage, transmitted from the switch circuit SC, of the non-inverting output voltage VOP and the inverting output voltage VON by using its second input terminal (e.g., an non-inverting input terminal), so as to control the gates of the transistor M3 and the transistor M4, so that the non-inverting output voltage VOP and the inverting output voltage VON are reset to be close to the reference voltage Vref. The switch SW1 is coupled between the second input terminal of the operational amplifier OP and the inverting output terminal NOUT. The switch SW2 is coupled between the second input terminal of the operational amplifier OP and the non-inverting output terminal POUT. The switches SW1 and SW2 are controlled by a periodically signal, for example, a clock signal with a duty ratio of 50%, but the present disclosure is not limited thereto. Therefore, the switches SW1 and SW2 are configured to be conducted periodically, and periodically capture the non-inverting output voltage VOP and the inverting output voltage VON to the second input terminal of the operational amplifier OP, so that the reset circuit 220 is configured to reset the non-inverting output voltage VOP and the inverting output voltage VON to be close to the reference voltage Vref.

In other words, when the switches SW1 and SW2 are turned on, the amplifier 200 uses the reference voltage Vref as a target to reset the non-inverting output voltage VOP and the inverting output voltage VON. When the switches SW1 and SW2 are turned off, the amplifier 200 uses an output of the differential input pair 210 as the non-inverting output voltage VOP and the inverting output voltage VON.

The compensation circuit 230 is coupled between the non-inverting input terminal PINa and the non-inverting output terminal POUT, is configured to generate a compensation voltage VF1 according to the non-inverting output voltage VOP, and is configured to provide the compensation voltage VF1 to the non-inverting input terminal PINa and the gate of the transistor M1. In some embodiments, the compensation voltage VF1 is positively correlated with the non-inverting output voltage VOP. In some embodiments, the compensation circuit 230 includes a capacitor C1 coupled between the non-inverting input terminal PINa and the non-inverting output terminal POUT.

The compensation circuit 240 is coupled between the inverting input terminal NINa and the inverting output terminal NOUT, is configured to generate a compensation voltage VF2 according to the inverting output voltage VON, and is configured to provide the compensation voltage VF2 to the inverting input terminal NINa and the gate of the transistor M2. In some embodiments, the compensation voltage VF2 is positively correlated with the inverting output voltage VON. In some embodiments, the compensation circuit 240 includes a capacitor C2 coupled between the inverting input terminal NINa and the inverting output terminal NOUT.

In some embodiments, capacitance of the gate-drain parasitic capacitors of the transistors M1 and M2 can be estimated by circuit simulation software. Wafer foundries usually provide their component models to their customers for simulating and verifying the circuit designs. The component models provided by the wafer foundries record relevant parameters of the parasitic capacitors of the transistors, so the capacitance of the parasitic capacitors can be calculated through circuit simulation software such as Spectre and Hspice. A capacitance of the capacitor C1 can be 50%-200% of the capacitance of the gate-drain parasitic capacitor of the transistor M1. A capacitance of the capacitor C2 can be 50%-200% of the capacitance of the gate-drain parasitic capacitor of the transistor M2.

In some embodiments, the capacitor C1 of the compensation circuit 230 can be replaced with a resistor coupled between the non-inverting input terminal PINa and the non-inverting output terminal POUT. The capacitor C2 of the compensation circuit 240 can be replaced with a resistor coupled between the inverting input terminal NINa and the inverting output terminal NOUT. The resistance of each of the aforementioned resistors can be obtained by the following Formula 1:

$$R = 1 / ( 2 \times π \times f \times C ) \times K \qquad Formula 1$$

In Formula 1, the symbol “R” represents the resistance; the symbol “f” represents main frequency of the non-inverting output voltage VOP and the inverting output voltage VON under a non-reset state; the symbol “C” represents a capacitance of a parasitic capacitor to be compensated (for example, if a resistance of the compensation circuit 230 is calculated using Formula 1, the symbol “C” is the capacitance of the gate-drain parasitic capacitor of the transistor M1); the symbol “K” is a constant between 0.5 and 2.

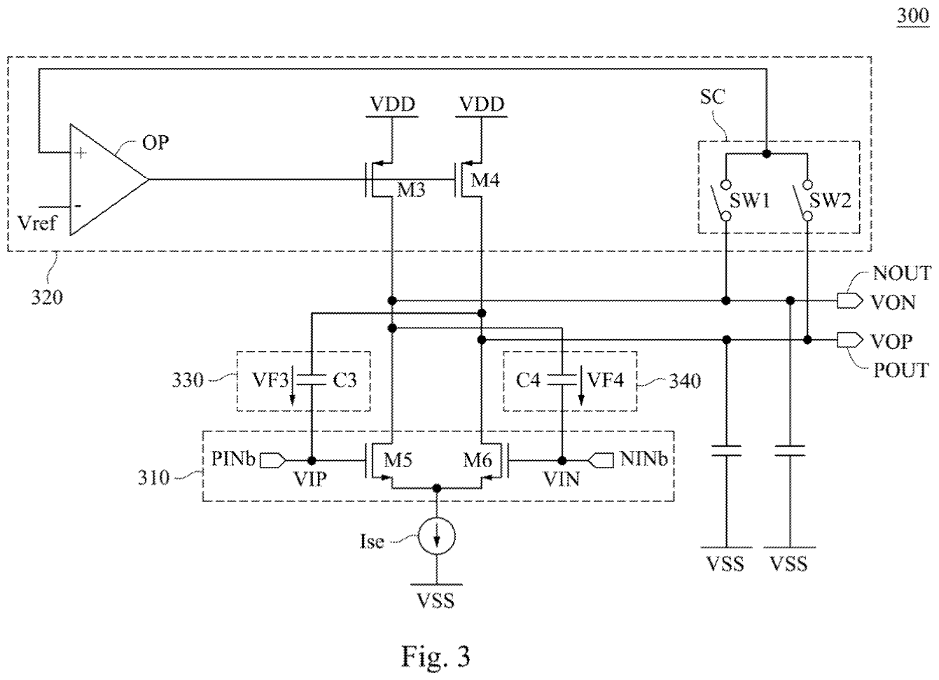

FIG. 3 depicts a schematic diagram of an amplifier 300 according to one embodiment of the present disclosure. The amplifier 300 includes a differential input pair 310, a reset circuit 320, a compensation circuit 330, a compensation circuit 340, a current source Ise, a non-inverting output terminal POUT and an inverting output terminal NOUT. The non-inverting output terminal POUT and the inverting output terminal NOUT are configured to respectively output the non-inverting output voltage VOP and the inverting output voltage VON. The current source Ise is coupled between a power supply terminal VSS and the differential input pair 310. The amplifier 300 uses compensation voltages VF3 and VF4 provided by the compensation circuits 330 and 340 to offset (or to compensate) negative feedbacks provided by the parasitic capacitors of the differential input pair 310 (not shown in FIG. 3), in order to compensate the gain of the amplifier 300 and ensure that the gain of the amplifier 300 will not be reduced due to the coupling effect of the parasitic capacitors.

The differential input pair 310 includes a transistor M5, a transistor M6, a non-inverting input terminal PINb and an inverting input terminal NINb. The non-inverting input terminal PINb and the inverting input terminal NINb are respectively configured to receive the non-inverting input voltage VIP and the inverting input voltage VIN. The differential input pair 310 is configured to amplify a voltage difference between the non-inverting input voltage VIP and the inverting input voltage VIN (i.e., a voltage difference between the non-inverting input terminal PINb and the inverting input terminal NINb), in order to provide the non-inverting output voltage VOP and the inverting output voltage VON to the non-inverting output terminal POUT and the inverting output terminal NOUT, respectively. The transistor M5 is coupled between the inverting output terminal NOUT and the current source Ise, and a gate of the transistor M5 is configured to receive the non-inverting input voltage VIP from the non-inverting input terminal PINb. The transistor M6 is coupled between the non-inverting output terminal POUT and the current source Ise, and a gate of the transistor M6 is configured to receive the inverting input voltage VIN from the inverting input terminal NINb. In addition, the transistors M5 and M6 are coupled to the power supply terminal VSS through the current source Ise.

The reset circuit 320 is similar to the reset circuit 220 in FIG. 2, the differences are that the transistor M3 of the reset circuit 320 is coupled between the power supply terminal VDD and the inverting output terminal NOUT and the transistor M4 of the reset circuit 320 is coupled between the power supply terminal VDD and the non-inverting output terminal POUT.

The compensation circuit 330 is coupled between the non-inverting input terminal PINb and the non-inverting output terminal POUT, is configured to generate a compensation voltage VF3 according to the non-inverting output voltage VOP, and is configured to provide the compensation voltage VF3 to the non-inverting input terminal PINb and the gate of the transistor M5. In some embodiments, the compensation voltage VF3 is positively correlated with the non-inverting output voltage VOP. In some embodiments, the compensation circuit 330 includes a capacitor C3 coupled between the non-inverting input terminal PINb and the non-inverting output terminal POUT.

The compensation circuit 340 is coupled between the inverting input terminal NINb and the inverting output terminal NOUT, is configured to generate a compensation voltage VF4 according to the inverting output voltage VON, and is configured to provide the compensation voltage VF4 to the inverting input terminal NINb and the gate of the transistor M6. In some embodiments, the compensation voltage VF4 is positively correlated with the inverting output voltage VON. In some embodiments, the compensation circuit 340 includes a capacitor C4 coupled between the inverting input terminal NINb and the inverting output terminal NOUT. The capacitance of the capacitors C3 and C4 can be determined in a manner similar to the aforementioned capacitors C1 and C2. For the sake of brevity, repetitious details are omitted herein.

In some embodiments, the capacitor C3 of the compensation circuit 330 can be replaced with a resistor coupled between the non-inverting input terminal PINb and the non-inverting output terminal POUT. The capacitor C4 of the compensation circuit 340 can be replaced with a resistor coupled between the inverting input terminal NINb and the inverting output terminal NOUT. Resistance of each of the aforementioned resistors can be calculated by the aforementioned Formula 1. For the sake of brevity, repetitious details are omitted herein.

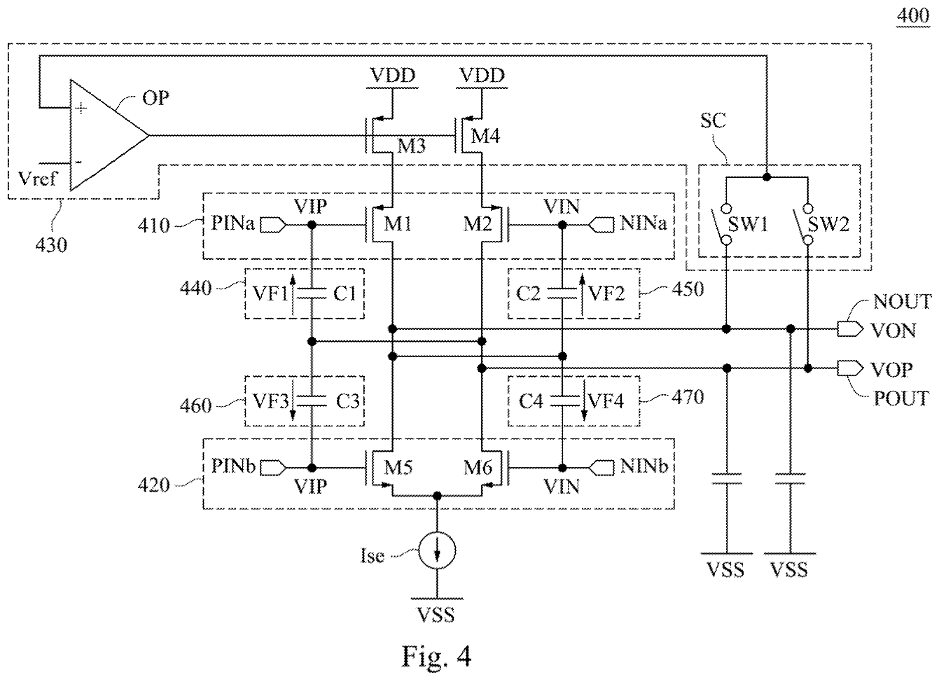

FIG. 4 depicts a schematic diagram of an amplifier 400 according to one embodiment of the present disclosure. The amplifier 400 includes a differential input pair 410, a differential input pair 420, a reset circuit 430, compensation circuits 440-470 and a current source Ise. Components, connection relationships, operations and advantages of the reset circuit 430 are similar to the reset circuit 320 in FIG. 3. For the sake of brevity, repetitious details are omitted herein.

The differential input pair 410, the compensation circuit 440 and the compensation circuit 450 are respectively similar to the differential input pair 210, the compensation circuit 230 and the compensation circuit 240 in FIG. 2. The differences are: the transistor M1 of the differential input pair 410 is coupled between the transistor M3 of the reset circuit 430 and the inverting output terminal NOUT; and the transistor M2 of the differential input pair 410 is coupled between the transistor M4 of the reset circuit 430 and the non-inverting output terminal POUT.

The differential input pair 420, the compensation circuit 460 and the compensation circuit 470 are respectively similar to the differential input pair 310, the compensation circuit 330 and the compensation circuit 340 in FIG. 3. The differences are: the capacitor C3 of the compensation circuit 460 and the capacitor C1 of the compensation circuit 440 are coupled in series between the non-inverting input terminals PINa and PINb, and the non-inverting output terminal POUT is coupled between the capacitors C1 and C3; and the capacitor C4 of the compensation circuit 470 and the capacitor C2 of the compensation circuit 450 are coupled in series between the inverting input terminals NINa and NINb, and the inverting output terminal NOUT is coupled between the capacitors C2 and C4.

As can be seen from the above, the differential input pair 410 is coupled in series to the differential input pair 420, and the differential input pairs 410 and 420 are configured to generate the non-inverting output voltage VOP and the inverting output voltage VON cooperatively.

In some embodiments, the capacitors C1 and C3 can be replaced with two resistors coupled in series between the non-inverting input terminals PINa and PINb, and the non-inverting output terminal POUT is coupled between the two resistors. The capacitors C2 and C4 can be replaced with another two resistors coupled in series between the inverting input terminals NINa and NINb, and the inverting output terminal NOUT is coupled between the another two resistors. Resistance of each of the aforementioned resistors can be calculated by the aforementioned Formula 1. For the sake of brevity, repetitious details are omitted herein.

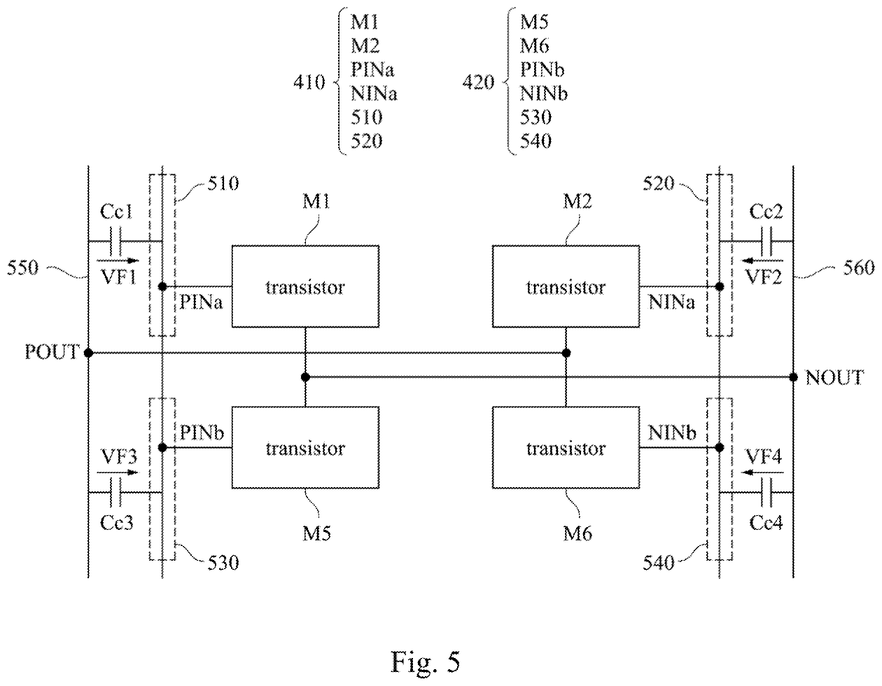

FIG. 5 depicts a schematic diagram of a partial circuit layout of the amplifier 400 of FIG. 4, according to one embodiment of the present disclosure. In the embodiment of FIG. 5, the compensation circuits 440-470 of FIG. 4 are respectively replaced with compensation capacitors Cc1-Cc4. In detail, in this embodiment, the differential input pair 410 further includes a non-inverting input wire 510 and an inverting input wire 520. The non-inverting input terminal PINa is located at the non-inverting input wire 510, and the inverting input terminal NINa is located at the inverting input wire 520. The differential input pair 420 further includes a non-inverting input wire 530 and an inverting input wire 540. The non-inverting input terminal PINb is located at the non-inverting input wire 530, and the inverting input terminal NINb is located at the inverting input wire 540. The non-inverting input wires 510 and 530 are coupled to each other, and the inverting input wires 520 and 540 are coupled to each other, but the present disclosure is not limited to this embodiment.

In addition, the amplifier 400 of the embodiment of FIG. 5 further includes a non-inverting output wire 550 and an inverting output wire 560. The non-inverting output terminal POUT is located at the non-inverting output wire 550, and the inverting output terminal NOUT is located at the inverting output wire 560. The non-inverting input wires 510 and 530 are configured to transmit the non-inverting input voltage VIP. The inverting input wires 520 and 540 are configured to transmit the inverting input voltage VIN. The non-inverting output wire 550 is configured to transmit the non-inverting output voltage VOP, and the inverting output wire 560 is configured to transmit the inverting output voltage VON.

In some embodiments, at least one portion of the non-inverting input wire 510 is disposed adjacent to the non-inverting output wire 550, and at least one portion of the non-inverting input wire 530 is disposed adjacent to the non-inverting output wire 550. As such, the compensation capacitor Cc1 is formed between the non-inverting input wire 510 and the non-inverting output wire 550, and the compensation capacitor Cc3 is formed between the non-inverting input wire 530 and the non-inverting output wire 550. At least one portion of inverting input wire 520 is disposed adjacent to the inverting output wire 560, and at least one portion of the inverting input wire 540 is disposed adjacent to the inverting output wire 560. As such, the compensation capacitor Cc2 is formed between the inverting input wire 520 and the inverting output wire 560, and the compensation capacitor Cc4 is formed between the inverting input wire 540 and the inverting output wire 560.

In some embodiments, the at least one portion of the non-inverting input wire 510 is disposed adjacent to and in parallel to the non-inverting output wire 550; the at least one portion of the non-inverting input wire 530 is disposed adjacent to and in parallel to the non-inverting output wire 550; the at least one portion of inverting input wire 520 is disposed adjacent to and in parallel to the inverting output wire 560; and the at least one portion of the inverting input wire 540 is disposed adjacent to and in parallel to the inverting output wire 560.

In other words, the compensation capacitors Cc1-Cc4 are parasitic capacitors between wires. The compensation capacitors Cc1-Cc4 are configured to provide the aforementioned compensation voltages VF1-VF4 respectively.

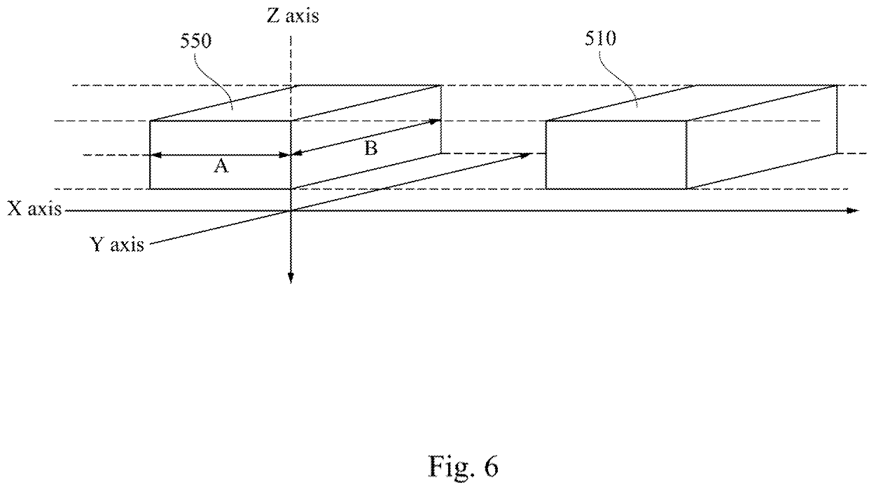

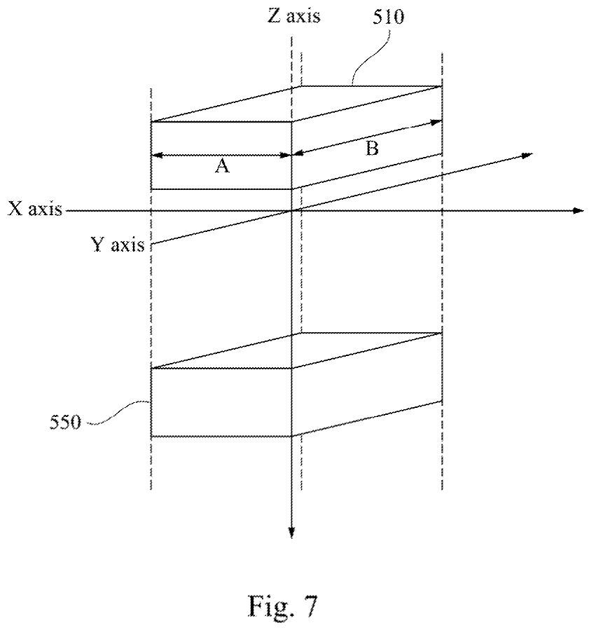

In some embodiments, no other wires are placed between wires adjacent to each other. For example, no other wires are placed between the non-inverting input wire 510 and the non-inverting output wire 550. In some embodiments, between the wires adjacent to each other, a vertical projection of one wire overlaps at least partially with a vertical projection of the other wire, and will be described in detail in following FIGS. 6-7.

FIGS. 6-7 depict schematic diagrams of arrangements of wires of FIG. 5, according to different embodiments of the present disclosure. For the sake of brevity, only positional relationships between the non-inverting input wire 510 and the non-inverting output wire 550 will be described below. A positional relationship between the non-inverting input wire 530 and the non-inverting output wire 550, a positional relationship between the inverting input wire 520 and the inverting output wire 560 and a positional relationship between the inverting input wire 540 and the inverting output wire 560 each can be set in a manner similar to the one described below. In embodiments of FIGS. 6-7, a vertical direction and a horizontal direction of part of the non-inverting input wire 510 and part of the non-inverting output wire 550 are respectively parallel to Y axis and X axis, that is, the part of the non-inverting input wire 510 and the part of the non-inverting output wire 550 extends in parallel to the Y axis. The X axis, the Y axis and the Z axis are perpendicular to each other.

Please refer to FIG. 6, in the embodiment of FIG. 6, the non-inverting input wire 510 and the non-inverting output wire 550 are located at the same metal layer. When the non-inverting input wire 510 is projected vertically toward the non-inverting output wire 550 in a direction of the X axis, the vertical projection of the non-inverting input wire 510 at least partially overlaps the non-inverting output wire 550, and vice versa.

Then, please refer to FIG. 7, in the embodiment of FIG. 7, the non-inverting input wire 510 and the non-inverting output wire 550 are located at different metal layers. When the non-inverting input wire 510 is projected vertically toward the non-inverting output wire 550 in a direction of the Z axis, the vertical projection of the non-inverting input wire 510 at least partially overlaps the non-inverting output wire 550, and vice versa.

In the aforementioned embodiments of FIGS. 6-7, each of the non-inverting input wire 510 and the non-inverting output wire 550 include a width “A”. In order to obtain a larger capacitance of the compensation capacitor Cc1, the portion of the non-inverting output wire 550 that overlapping with the vertical projection of the non-inverting input wire 510 includes a length “B”, where “A” and “B” are positive numbers and “B” is greater than or equal to “A”.

In some embodiments, in a manner similar to those described above, the compensation circuits 230 and 240 of the amplifier 200 of FIG. 2 may be replaced with the compensation capacitors Cc1 and Cc2, respectively, through including the non-inverting input wire 510, the inverting input wire 520, the non-inverting output wire 550 and the inverting output wire 560 in the amplifier 200. In a manner similar to the method described above, the compensation circuits 330 and 340 of the amplifier 300 of FIG. 3 may be replaced with the compensation capacitors Cc3 and Cc4, respectively, by including the non-inverting input wire 530, the inverting input wire 540, the non-inverting output wire 550 and the inverting output wire 560 in the amplifier 300.

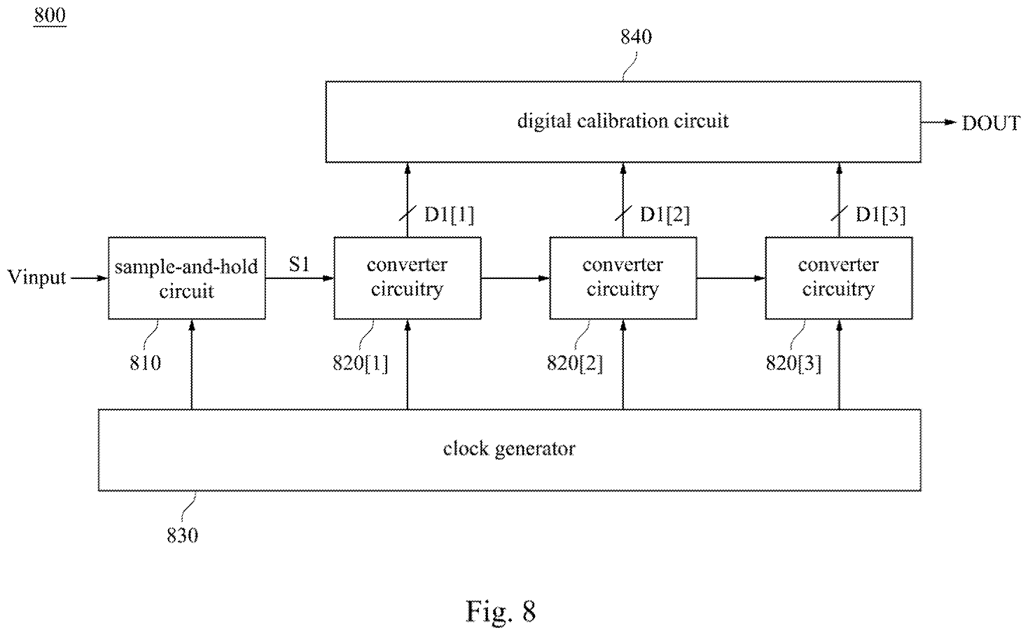

FIG. 8 depicts a simplified functional block diagram of a pipelined analog-to-digital convertor 800 according to one embodiment of the present disclosure. The pipelined analog-to-digital convertor 800 includes a sample-and-hold circuit 810, a plurality of convertor circuitries 820[1]-820[3], a clock generator 830, and a digital calibration circuit 840.

The sample-and-hold circuit 810 is configured to sample an input signal Vinput. The plurality of convertor circuitries 820[1]-820[3] are configured to sequentially convert outputs of the previous stages into a plurality of digital codes D1[1]-D1[3]. The convertor circuitry 820[1] is configured to convert a sampling result of the sample-and-hold circuit 810 to the input signal Vinput. A number of the convertor circuitries 820[1]-820[3] is merely an example, and the present disclosure is not limited thereto. The clock generator 830 is configured to generate a plurality of clock signals to the sample-and-hold circuit 810 and the convertor circuitries 820[1]-820[3] to make the sample-and-hold circuit 810 and the convertor circuitries 820[1]-820[3] execute aforementioned operations according to the clock signals. The digital calibration circuit 840 is configured to combine the digital codes D1 [1]-D1 [3] to generate a digital code DOUT. In some embodiments, the digital calibration circuit 840 is configured to calibrate offset errors and/or gain errors of the convertor circuitries 820[1]-820[3].

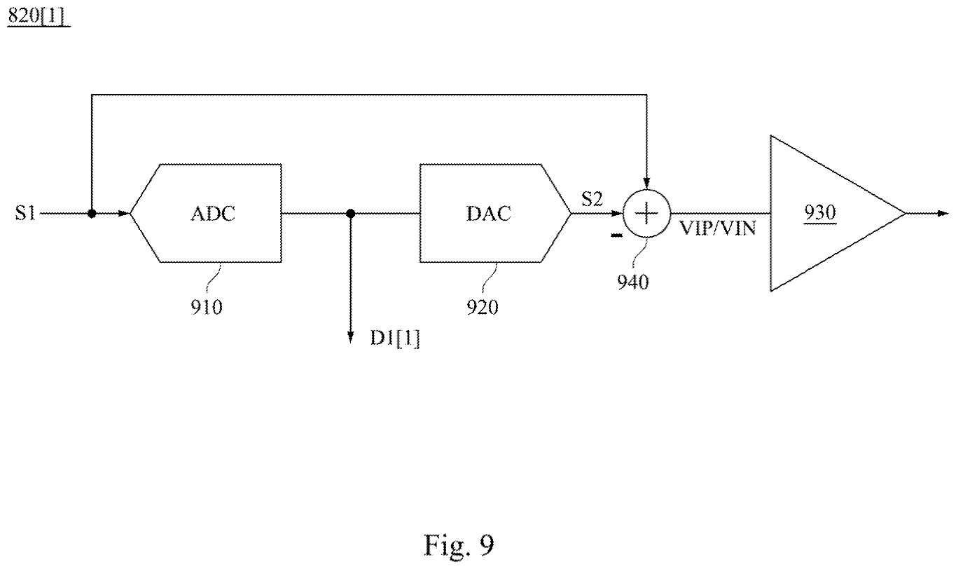

FIG. 9 depicts a simplified functional block diagram of the pipelined analog-to-digital convertor circuitry 820[1] according to one embodiment of the present disclosure. Components, connection relationships, operation and advantages of the convertor circuitries 820[1]-820[3] are similar to each other, and therefore only the convertor circuitry 820[1] will be described below. The convertor circuitry 820[1] includes an analog-to-digital convertor 910, a digital-to-analog convertor 920, an amplifier 930 and a subtractor 940.

The analog-to-digital convertor 910 is configured to convert an output (hereinafter referred to as a signal S1) of the sample-and-hold circuit 810 to generate the digital code D1[1]. In some embodiments, the analog-to-digital convertor 910 can be implemented using a successive approximation analog-to-digital convertor (SAR ADC). The digital-to-analog convertor 920, the amplifier 930 and the subtractor 940 are configured to cooperatively process the signal S1 and the digital code D1 [1], in order to generate a residual signal as an output of the convertor circuitry 820[1]. In some embodiments, the amplifier 930 can be implemented using one of the amplifiers 200, 300 and 400 in the aforementioned embodiments.

In detail, the digital-to-analog convertor 920 is configured to convert the digital code D1 [1] to a signal S2, and the subtractor 940 is configured to subtract the signal S2 from the signal S1, in order to output the aforementioned non-inverting input voltage VIP and the inverting input voltage VIN to the amplifier 930. The amplifier 930 is configured to amplify a voltage difference between the non-inverting input voltage VIP and the inverting input voltage VIN in order to generate the residual signal.

Certain terms are used in the specification and the claims to refer to specific components. However, those of ordinary skill in the art would understand that the same components may be referred to by different terms. The specification and claims do not use the differences in terms as a way to distinguish components, but the differences in functions of the components are used as a basis for distinguishing. Furthermore, it should be understood that the term “comprising” used in the specification and claims is open-ended, that is, including but not limited to. In addition, “coupling” herein includes any direct and indirect connection means. Therefore, if it is described that the first component is coupled to the second component, it means that the first component can be directly connected to the second component through electrical connection or signal connections including wireless transmission, optical transmission, and the like, or the first component is indirectly electrically or signally connected to the second component through other component(s) or connection means.

It will be understood that, in the description herein and throughout the claims that follow, the phrase “and/or” includes any and all combinations of one or more of the associated listed items. Unless the context clearly dictates otherwise, the singular terms used herein include plural referents.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. An amplifier, comprising:
a first differential input pair, comprising a first non-inverting input terminal and a first inverting input terminal, and configured to amplify a voltage difference between the first non-inverting input terminal and the first inverting input terminal in order to generate a non-inverting output voltage and an inverting output voltage of the amplifier;
a reset circuit, coupled to the first differential input pair, and configured to reset the non-inverting output voltage and the inverting output voltage of the amplifier according to a reference voltage;
a first compensation circuit, configured to provide a first compensation voltage to the first non-inverting input terminal, wherein the first compensation voltage is positively correlated with the non-inverting output voltage; and
a second compensation circuit, configured to provide a second compensation voltage to the first inverting input terminal, wherein the second compensation voltage is positively correlated with the inverting output voltage.

2. The amplifier of claim 1, further comprising:
a non-inverting output terminal, configured to output the non-inverting output voltage; and
an inverting output terminal, configured to output the inverting output voltage,
wherein the first compensation circuit comprises a first capacitor, wherein the first capacitor is coupled between the first non-inverting input terminal and the non-inverting output terminal,
wherein the second compensation circuit comprises a second capacitor, wherein the second capacitor is coupled between the first inverting input terminal and the inverting output terminal.

3. The amplifier of claim 1, further comprising:
a non-inverting output terminal, configured to output the non-inverting output voltage; and
an inverting output terminal, configured to output the inverting output voltage,
wherein the first compensation circuit comprises a first resistor, wherein the first resistor is coupled between the first non-inverting input terminal and the non-inverting output terminal,
wherein the second compensation circuit comprises a second resistor, wherein the second resistor is coupled between the first inverting input terminal and the inverting output terminal.

4. The amplifier of claim 1, further comprising:
a second differential input pair, comprising a second non-inverting input terminal and a second inverting input terminal, configured to amplify a voltage difference between the second non-inverting input terminal and the second inverting input terminal, and coupled in series to the first differential input pair, in order to generate the non-inverting output voltage and the inverting output voltage with the first differential input pair;
a third compensation circuit, configured to provide a third compensation voltage to the second non-inverting input terminal, wherein the third compensation voltage is positively correlated with the non-inverting output voltage; and
a fourth compensation circuit, configured to provide a fourth compensation voltage to the second inverting input terminal, wherein the fourth compensation voltage is positively correlated with the inverting output voltage.

5. The amplifier of claim 4, further comprising:
a non-inverting output terminal, configured to output the non-inverting output voltage; and
an inverting output terminal, configured to output the inverting output voltage,
wherein the first compensation circuit, the second compensation circuit, the third compensation circuit and the fourth compensation circuit respectively comprise a first capacitor, a second capacitor, a third capacitor and a fourth capacitor,
wherein the first capacitor and the third capacitor are coupled in series between the first non-inverting input terminal and the second non-inverting input terminal, and the non-inverting output terminal is coupled between the first capacitor and the third capacitor,
wherein the second capacitor and the fourth capacitor are coupled in series between the first inverting input terminal and the second inverting input terminal, and the inverting output terminal is coupled between the second capacitor and the fourth capacitor.

6. The amplifier of claim 4, further comprising:
a non-inverting output terminal, configured to output the non-inverting output voltage; and
an inverting output terminal, configured to output the inverting output voltage,
wherein the first compensation circuit, the second compensation circuit, the third compensation circuit and the fourth compensation circuit respectively comprise a first resistor, a second resistor, a third resistor and a fourth resistor,
wherein the first resistor and the third resistor are coupled in series between the first non-inverting input terminal and the second non-inverting input terminal, and the non-inverting output terminal is coupled between the first resistor and the third resistor,
wherein the second resistor and the fourth resistor are coupled in series between the first inverting input terminal and the second inverting input terminal, and the inverting output terminal is coupled between the second resistor and the fourth resistor.

7. The amplifier of claim 4, further comprising:
a non-inverting output terminal, configured to output the non-inverting output voltage; and
an inverting output terminal, configured to output the inverting output voltage,
wherein the reset circuit comprises:
an operational amplifier, comprising a first input terminal and a second input terminal, wherein the first input terminal is configured to receive the reference voltage;
a first transistor;
a second transistor, wherein the first transistor and the second transistor are controlled by the operational amplifier, and are coupled to the inverting output terminal and the non-inverting output terminal, respectively, through the first differential input pair; and
a switch circuit, configured to be conducted periodically, in order to transmit a common mode voltage of the non-inverting output voltage and the inverting output voltage to the second input terminal of the operational amplifier.

8. The amplifier of claim 1, further comprising:
a non-inverting output terminal, configured to output the non-inverting output voltage; and
an inverting output terminal, configured to output the inverting output voltage,
wherein the reset circuit comprises:
an operational amplifier, comprising a first input terminal and a second input terminal, wherein the first input terminal is configured to receive the reference voltage;
a first transistor, coupled to the inverting output terminal;
a second transistor, coupled to the non-inverting output terminal, wherein the first transistor and the second transistor are controlled by the operational amplifier; and
a switch circuit, configured to be conducted periodically, in order to transmit a common mode voltage of the non-inverting output voltage and the inverting output voltage to the second input terminal of the operational amplifier.

9. An amplifier, comprising:
a first differential input pair, comprising a first non-inverting input wire and a first inverting input wire, and configured to amplify a voltage difference between the first non-inverting input wire and the first inverting input wire in order to generate a non-inverting output voltage and an inverting output voltage of the amplifier;
a reset circuit, coupled to the first differential input pair, and configured to reset the non-inverting output voltage and the inverting output voltage of the amplifier according to a reference voltage;
a non-inverting output wire, configured to transmit the non-inverting output voltage, wherein a portion of the non-inverting output wire is disposed adjacent to the first non-inverting input wire to form a first compensation capacitor with the first non-inverting input wire, wherein the first compensation capacitor is configured to provide a first compensation voltage positively correlated with the non-inverting output voltage to the first non-inverting input wire; and
an inverting output wire, configured to transmit the inverting output voltage, wherein a portion of the inverting output wire is disposed adjacent to the first inverting input wire to form a second compensation capacitor with the first inverting input wire, wherein the second compensation capacitor is configured to provide a second compensation voltage positively correlated with the inverting output voltage to the first inverting input wire.

10. The amplifier of claim 9, further comprising:
a second differential input pair, comprising a second non-inverting input wire and a second inverting input wire, configured to amplify a voltage difference between the second non-inverting input wire and the second inverting input wire, and coupled in series to the first differential input pair, in order to generate the non-inverting output voltage and the inverting output voltage together with the first differential input pair,
wherein another portion of the non-inverting output wire is disposed adjacent to the second non-inverting input wire to form a third compensation capacitor with the second non-inverting input wire,
wherein another portion of the inverting output wire is disposed adjacent to the second inverting input wire to form a fourth compensation capacitor with the second inverting input wire.

11. The amplifier of claim 10, wherein the reset circuit comprises:
an operational amplifier, comprising a first input terminal and a second input terminal, wherein the first input terminal is configured to receive the reference voltage;
a first transistor;
a second transistor, wherein the first transistor and the second transistor are controlled by the operational amplifier, and are coupled to the inverting output wire and the non-inverting output wire through the first differential input pair respectively; and
a switch circuit, configured to be conducted periodically, in order to transmit a common mode voltage of the non-inverting output voltage and the inverting output voltage to the second input terminal of the operational amplifier.

12. The amplifier of claim 9, wherein the reset circuit comprises:
an operational amplifier, comprising a first input terminal and a second input terminal, wherein the first input terminal is configured to receive the reference voltage;
a first transistor, coupled to the inverting output wire;
a second transistor, coupled to the non-inverting output wire, wherein the first transistor and the second transistor are controlled by the operational amplifier; and
a switch circuit, configured to be conducted periodically, in order to transmit a common mode voltage of the non-inverting output voltage and the inverting output voltage to the second input terminal of the operational amplifier.

13. A pipelined analog-to-digital convertor (ADC), comprising a convertor circuitry, wherein the convertor circuitry comprises:
an analog-to-digital convertor;
a digital-to-analog convertor (DAC), configured to convert an output of the ADC;
a subtractor, configured to subtract the output of the DAC from an input of the ADC; and
an amplifier, comprising:
a first differential input pair, comprising a first non-inverting input terminal and a first inverting input terminal configured to receive an output of the subtractor, and configured to amplify a voltage difference between the first non-inverting input terminal and the first inverting input terminal in order to generate a non-inverting output voltage and an inverting output voltage of the amplifier;
a reset circuit, coupled to the first differential input pair, and configured to reset the non-inverting output voltage and the inverting output voltage of the amplifier according to the a reference voltage;
a first compensation circuit, configured to provide a first compensation voltage to the first non-inverting input terminal, wherein the first compensation voltage is positively correlated with the non-inverting output voltage; and
a second compensation circuit, configured to provide a second compensation voltage to the first inverting input terminal, wherein the second compensation voltage is positively correlated with the inverting output voltage.

14. The pipelined ADC of claim 13, wherein amplifier further comprises:
a non-inverting output terminal, configured to output the non-inverting output voltage; and
an inverting output terminal, configured to output the inverting output voltage,
wherein the first compensation circuit comprises a first capacitor, wherein the first capacitor is coupled between the first non-inverting input terminal and the non-inverting output terminal,
wherein the second compensation circuit comprises a second capacitor, wherein the second capacitor is coupled between first inverting input terminal and the inverting output terminal.

15. The pipelined ADC of claim 13, wherein the amplifier further comprises:
a non-inverting output terminal, configured to output the non-inverting output voltage; and
an inverting output terminal, configured to output the inverting output voltage,
wherein the first compensation circuit comprises a first resistor, wherein the first resistor is coupled between the first non-inverting input terminal and the non-inverting output terminal,
wherein the second compensation circuit comprises a second resistor, wherein the second resistor is coupled between the first inverting input terminal and the inverting output terminal.

16. The pipelined ADC of claim 13, wherein the amplifier further comprises:
a second differential input pair, comprising a second non-inverting input terminal and a second inverting input terminal configured to receive an output of the subtractor, configured to amplify a voltage difference between the second non-inverting input terminal and the second inverting input terminal, and coupled in series to the first differential input pair, in order to generate the non-inverting output voltage and the inverting output voltage together with the first differential input pair;
a third compensation circuit, configured to provide a third compensation voltage to the second non-inverting input terminal, wherein the third compensation voltage is positively correlated with the non-inverting output voltage; and
a fourth compensation circuit, configured to a provide a fourth compensation voltage to the second inverting input terminal, wherein the fourth compensation voltage is positively correlated with the inverting output voltage.

17. The pipelined ADC of claim 16, wherein the amplifier further comprises:
a non-inverting output terminal, configured to output the non-inverting output voltage; and
an inverting output terminal, configured to output the inverting output voltage,
wherein the first compensation circuit, the second compensation circuit, the third compensation circuit and the fourth compensation circuit respectively comprise a first capacitor, a second capacitor, a third capacitor and a fourth capacitor,
wherein the first capacitor and the third capacitor are coupled in series between the first non-inverting input terminal and the second non-inverting input terminal, and the non-inverting output terminal is coupled between the first capacitor and the third capacitor,
wherein the second capacitor and the fourth capacitor are coupled in series between the first inverting input terminal and the second inverting input terminal, and the inverting output terminal is coupled between the second capacitor and the fourth capacitor.

18. The pipelined ADC of claim 16, wherein the amplifier further comprises:
a non-inverting output terminal, configured to output the non-inverting output voltage; and
an inverting output terminal, configured to output the inverting output voltage,
wherein the first compensation circuit, the second compensation circuit, the third compensation circuit and the fourth compensation circuit respectively comprise a first resistor, a second resistor, a third resistor and a fourth resistor,
wherein the first resistor and the third resistor are coupled in series between the first non-inverting input terminal and the second non-inverting input terminal, and the non-inverting output terminal is coupled between the first resistor and the third resistor,
wherein the second resistor and the fourth resistor are coupled in series between the first inverting input terminal and the second inverting input terminal, and the inverting output terminal is coupled between the second resistor and the fourth resistor.

19. The pipelined ADC of claim 16, wherein the amplifier further comprises:
a non-inverting output terminal, configured to output the non-inverting output voltage; and
an inverting output terminal, configured to output the inverting output voltage,
wherein the reset circuit comprises:
an operational amplifier, comprising a first input terminal and a second input terminal, wherein the first input terminal is configured to receive the reference voltage;
a first transistor;
a second transistor, wherein the first transistor and the second transistor are controlled by the operational amplifier, and are coupled to the inverting output terminal and the non-inverting output terminal through the first differential input pair respectively; and
a switch circuit, configured to be conducted periodically, in order to transmit a common mode voltage of the non-inverting output voltage and the inverting output voltage to the second input terminal of the operational amplifier.

20. The pipelined ADC of claim 13, wherein the amplifier further comprises:
a non-inverting output terminal, configured to output the non-inverting output voltage; and
an inverting output terminal, configured to output the inverting output voltage,
wherein the reset circuit comprises:
an operational amplifier, comprising a first input terminal and a second input terminal, wherein the first input terminal is configured to receive the reference voltage;
a first transistor, coupled to the inverting output terminal;
a second transistor, coupled to the non-inverting output terminal, wherein the first transistor and the second transistor are controlled by the operational amplifier; and
a switch circuit, configured to be conducted periodically, in order to transmit a common mode voltage of the non-inverting output voltage and the inverting output voltage to the second input terminal of the operational amplifier.
